(19) United States
(12) Patent Application Publication
(10) Pub. No.: US 2025/0298166 A1
(43) Pub. Date: Sep. 25, 2025

(54) INDUCTIVE PROXIMITY SENSOR, SENSOR SYSTEM INCLUDING INDUCTIVE PROXIMITY SENSORS AND METHOD FOR OPERATING SUCH A SENSOR SYSTEM

(71) Applicant: Pepperl+Fuchs SE, Mannheim (DE)

(72) Inventors: Christoph BRAUNSMANN, Mannheim (DE); Heiko HÖBEL, Mannheim (DE); Caroline SCHAEUBLE, Mannheim (DE)

(73) Assignee: Pepperl+Fuchs SE, Mannheim (DE)

(21) Appl. No.: 19/032,611

(22) Filed: Jan. 21, 2025

(30) Foreign Application Priority Data
Jan. 29, 2024 (EP) 24154464.2

(51) Int. Cl. G01V 3/10; G01V 3/38

(52) U.S. Cl. CPC G01V 3/10; G01V 3/38

(57) ABSTRACT

The invention relates to an inductive proximity sensor, comprising:
a sensor coil;
a pulse evaluation circuit which is configured to provide an excitation pulse for the sensor coil and to obtain a resulting voltage response;
a control unit which is configured to
   to control the pulse evaluation circuit according to a pulse evaluation process such that the sensor coil is excited by an excitation pulse of a predetermined duration of time;
   to detect at least a first measurement voltage at a specific first point in time after providing the excitation pulse, and
   to provide an indication regarding the presence or absence of an object to be detected in a detection area around a sensor coil,
      wherein a synchronization unit is provided in order to receive a synchronization signal which indicates if or when a pulse evaluation process is active in an adjacent proximity sensor, and in that the control unit is configured to start the pulse evaluation process in dependence on the synchronization signal.

### TECHNICAL FIELD

The invention relates to inductive proximity sensors for measuring the presence of a conductive object to be detected in an area of detection using a pulse evaluation process and measures for avoiding measurement errors in two inductive proximity sensors adjacent to each other due to crosstalk of an excitation current pulse between sensor coils.

### TECHNICAL BACKGROUND

Inductive proximity sensors may determine the presence or absence of a conductive object to be detected using a pulse evaluation process. Here, a current pulse is impressed into a sensor coil, and the voltage response is evaluated. The course of the voltage response depends on the proximity of the conductive object to be detected in the proximity of the sensor coil. The voltage response varies due to the induction of eddy currents in the object to be detected, so that an analysis of the course, e.g. in the form of a measurement of the amplitude of the voltage response after a predetermined period of time after the coil current has dropped to 0 A, allows a detection of an object to be detected which is in proximity to the sensor coil.

Such inductive proximity sensors, which are based on the principle of pulse evaluation, are known, for example, from documents EP0492029B1 and EP4030623A1.

In some applications, it may be necessary to operate several identical inductive proximity sensors in close proximity to each other. This may be provided, for example, for the measurement of object speeds, detect several objects in a limited space or to achieve measurement redundancy. If the sensor coils of the proximity sensors are arranged to be close to each other, there is a magnetic coupling with a non-negligible coupling factor between the sensor coils. Thus, a time-varying magnetic field caused by one of the sensor coils may induce interference voltages in the sensor coil of another one of the proximity sensors, which may have an effect in the form of an interference signal when evaluating a voltage response in the sensor coil of the other proximity sensor, and may thus significantly interfere with the signal evaluation thereof.

In the case of several adjacent inductive proximity sensors with pulse evaluation, the momentary time offset of the cyclic current pulses and the type of pulse evaluation of the voltage response determine whether or not the two pulse evaluations of the proximity sensors interfere with or influence each other. Since the period duration of the cyclic current pulses differs slightly between the proximity sensors, as the clock sources of the control units in the proximity sensors are subject to scattering, the phase position of the cyclic current pulses also changes and typically modulates with the difference in the frequencies of the cyclic current pulses in terms of strength and direction of effect of the mutual interference. Thus, by specifying a phase position, it may not automatically be ruled out that the pulse evaluation for an inductive proximity sensor is not disturbed by the operation of the adjacent proximity sensor.

Document DE 10 2011 018 430 A1 discloses an inductive proximity switch comprising a circuit through which a coil is electrically connected to a voltage source and in which a capacitor is provided through which an induction voltage is detected, and an evaluation device through which a switching signal is generated when a threshold voltage of the capacitor is exceeded, the voltage supply of the coil being shifted by the evaluation device in dependence on induction voltages of the capacitor measured over time, and in that the evaluation device detects this voltage immediately before the coil is connected to the voltage source by means of the voltage measured at the capacitor.

Shortly before the start of a new pulse, each sensor detects the pulse voltage using a capacitor. If the capacitor voltage is above a specific threshold value, an interference from an adjacent sensor is assumed. To avoid this interference, the start of the subsequent pulse is delayed by a specific period of time. This allows the sensors to synchronize with a time delay with a phase position that is not critical, i.e. the sensors can no longer interfere with each other after one or a few periods. Thereby, the faster of the two sensors adjusts its pulse period on average to the period of the slower sensor.

The disadvantage of such an inductive self-synchronization is that the coupling must not fall below a minimum level for the adjacent proximity sensor to be detected, and therefore a specific minimum distance must not be exceeded. If the minimum distance is exceeded or the inductive coupling is briefly reduced by the approach of an object to be detected, the synchronization of the proximity sensors may be lost, so that two adjacent proximity sensors may still influence each other under certain circumstances. Therefore, a reliable synchronization cannot be guaranteed.

Alternatively, the phase position between the cyclic current pulses of the plurality of the proximity sensors for each pulse period may significantly be changed, so that clearly differing disturbing influences may be detected for each measurement. By using suitable digital filters, short-term fluctuations in the voltage response at specific phase positions may be filtered out as anomalies so that measurement values with a high level of interference may be eliminated.

However, such a process is disadvantageous in that the filtering reduces the average measurement rate of the proximity sensors, which also fluctuates due to the sporadic elimination of individual measurement values.

Document EP 3531557 A1 discloses a proximity sensor for detecting a detection object using a magnetic field, comprising a detection coil for generating the magnetic field, an excitation circuit for repeatedly supplying a pulsed excitation current to the detection coil, a detection circuit for detecting the detection object based on a voltage which is generated at both ends of the detection coil during a predetermined period of time after the supply of the excitation current is interrupted, and a control circuit for controlling the excitation circuit so that a time of cutting off the supply of the excitation current to the detection coil becomes aperiodic.

It is an object of the present invention to provide an inductive proximity sensor in which, in a sensor system with a plurality of proximity sensors, interference in the pulse evaluation due to the operation of adjacent inductive proximity sensors may be avoided and the measurement rate is not impaired.

### DISCLOSURE OF THE INVENTION

This object is solved by the inductive proximity sensor according to claim 1, the sensor system having a plurality of inductive proximity sensors, and the method for operating a sensor system according to the independent claims.

Further embodiments are specified in the dependent claims.

According to a first aspect, an inductive proximity sensor is provided, comprising
a sensor coil,
a pulse evaluation circuit which is configured to provide an excitation pulse for the sensor coil and to obtain a resulting voltage response;
a control unit which is configured to
   control the pulse evaluation circuit in accordance with a pulse evaluation process so that the sensor coil is excited with an excitation pulse having a predetermined duration;
   detect at least a first measurement voltage at a specific first point in time after the excitation pulse has been provided, and
   provide an indication of the presence or absence of an object to be detected in a detection area around the sensor coil,
wherein a synchronization unit is provided to receive a synchronization signal indicating if or when a pulse evaluation process is active in an adjacent proximity sensor, and that the control unit is configured to start the pulse evaluation process based on the synchronization signal.

Furthermore, the control unit may be configured to start the pulse evaluation process only if no pulse evaluation process is active in an adjacent proximity sensor.

The synchronization unit may be configured to signal the time and duration of the active pulse evaluation process under the control of the control unit.

According to an embodiment, the detection of the first measurement voltage may be carried out at a specific first point in time after a coil current of 0 A has been reached or after the falling edge of the excitation pulse. The excitation pulse may correspond to a current or voltage square-wave pulse of a predetermined duration.

According to an embodiment, if it is detected that the pulse evaluation process is active in an adjacent proximity sensor, the control unit may be configured to start the pulse evaluation process when the pulse evaluation process in the adjacent proximity sensor has ended.

Furthermore, the control unit may be configured to determine a voltage difference between the first measurement voltage and a second measurement voltage, and to provide it as an indication of the presence or absence of an object to be detected in a detection area of the sensor coil, the control unit being configured to detect the second measurement voltage at a specific second point in time after the excitation pulse has been provided, e.g. after a coil current of 0 A has been reached or after the falling edge of the excitation pulse, after the first point in time.

The operation of an inductive proximity sensor is usually controlled by a control unit, which may include a microcontroller, for example. In general, a current pulse is periodically impressed into a sensor coil, and the resulting voltage response is evaluated after the coil current is switched off. The voltage response is evaluated by measuring a first measurement voltage of a resulting voltage response at a time after the excitation pulse has been provided, such as immediately or shortly after the falling edge of the current pulse or after reaching a coil current of 0 A, and optionally a second measurement voltage after a predetermined longer period of time after providing the excitation pulse, such as after the falling edge of the current pulse or after reaching a coil current of 0 A, in order to obtain a reference value to which the first measurement voltage refers. The voltage difference between the two measurement voltages then provides a representative value of the voltage response, which may be used to determine the presence or absence of an object to be detected using a threshold value comparison.

Applying the current pulse to the sensor coil causes a changing magnetic field in the proximity of the sensor coil. If several sensor coils are arranged to be in close proximity to each other, so that a current pulse in one sensor coil causes a voltage pulse in an adjacent sensor coil, the evaluation of the voltage responses may be affected. In order to avoid mutual interference in the evaluation of a voltage response using the pulse evaluation process of several adjacent inductive proximity sensors, it is necessary to ensure during the voltage measurement to obtain the measurement voltages that no interference occurs due to the application of a current pulse to a sensor coil of an adjacent inductive proximity sensor.

If a disturbance occurs in an adjacent inductive proximity sensor during one of the voltage measurements due to an edge of a current pulse through a sensor coil, the voltage measurement will be falsified. To ensure that the voltage for the voltage response may be measured without disturbing influences, the operations of the inductive proximity switches of the sensor system are synchronized with each other.

An electrical synchronization line may be provided to transmit the synchronization signal. The synchronization signal may use a first voltage level to indicate that no pulse evaluation process is active, and a second voltage level to indicate that a pulse evaluation process is active.

In order to coordinate the operation of two or more than two inductive proximity sensors, they may be connected to each other via a synchronization line. A synchronization signal is applied to the synchronization line by a proximity sensor, which indicates when a pulse evaluation process is currently active or a pulse evaluation is being carried out by the pulse evaluation process in the relevant proximity sensor. If a proximity sensor detects through a synchronization circuit that a pulse evaluation is currently active or taking place in another proximity sensor, the start of a pending pulse evaluation process, which begins with the generation of the current pulse by the sensor coil, is delayed. This stops the measurement cycle of the relevant proximity sensor until the synchronization signal indicates that no pulse evaluation process is currently active.

The synchronization signal may be defined such that a first voltage level is used to signal that no pulse evaluation process is currently active and a second voltage level is used to signal that a pulse evaluation process is currently active. Applying the first voltage level may therefore signal that a measurement may be carried out with another inductive proximity sensor after the voltage response has been evaluated. The pulse evaluation process is active while the current pulse is being applied and for a predetermined period of time after the excitation pulse has been provided. At least the first measurement voltage, and, if applicable, the second measurement voltage is measured within the specified time period.

The synchronization line is connected to all proximity sensors in close proximity to each other and may use the voltage level to indicate whether a pulse evaluation process may be started or not. For this purpose, a synchronization unit is provided in each of the proximity sensors, which provides the second voltage level on the synchronization line by means of a corresponding pull-up or pull-down resistor when the pulse evaluation process is active or detects the voltage level on the synchronization line as an input signal for the control unit of the relevant proximity sensor when the pulse evaluation process is not active.

In particular, a synchronization process is used to indicate when a pulse evaluation process is active in one of the proximity sensors, thus blocking the execution of the pulse evaluation process in the other proximity sensors of the sensor system.

In normal operation, the control unit of the proximity sensor provides a periodic or cyclical supply of the current pulse for the pulse evaluation process. Before the current pulse is applied, it is checked whether the voltage level on the synchronization line indicates that no pulse evaluation process is active (at the first voltage level). If this is the case, the control unit carries out the pulse evaluation process and sets the voltage level on the synchronization line so that it indicates that a pulse evaluation process is active (second voltage level). If, on the other hand, a second voltage level is detected on the synchronization line before the pulse evaluation process is started, which indicates that a pulse evaluation process is active, the pending pulse evaluation process is delayed and it is waited until the voltage level on the synchronization line indicates that no pulse evaluation process is taking place (by changing to the first voltage level). For this purpose, the voltage level on the synchronization line may be regularly, in particular periodically, queried in the control unit or the requested pulse evaluation process may then be delayed and not performed overlapping with the pulse evaluation process taking place previously by temporarily lengthening or shortening the pulse period of the cyclically performed pulse evaluation process.

Furthermore, it may be provided that the control unit is configured to start the pulse evaluation process if the synchronization signal indicates for more than a predetermined period of time that a pulse evaluation process is active in an adjacent proximity sensor.

In particular, the control unit may thus determine that a pulse evaluation process is active via the synchronization line for a predetermined period of time, and if the period of time is exceeded, the pulse evaluation process may be started regardless of the voltage level on the synchronization line in order to prevent the measurement cycles for a proximity sensor from being permanently deactivated and measurements no longer being able to be taken.

Furthermore, the control unit may be configured to set the voltage level of the synchronization signal to the second voltage level when or before the excitation pulse is applied and/or to set the voltage level of the synchronization signal to the first voltage level after at least the first measurement voltage or, if applicable, also the second measurement voltage has been detected.

The synchronization signal may specify a clock in cyclical operation of the pulse evaluation process. The starts of the pulse evaluation process may then be based on this clock, whereby each of the proximity sensors starts the pulse evaluation process with an individual phase position in relation to the clock signal. The synchronization line may then be used to assign the cycle frequency and the individual phase positions to the proximity sensors when the sensor system is started.

According to a further aspect, a sensor system comprising a plurality of the above proximity sensors is provided, wherein the proximity sensors are interconnected via a synchronization line.

According to a further aspect, a method for operating an inductive proximity sensor with a sensor coil is provided, comprising the following steps:
Providing an excitation pulse to apply on the sensor coil with a predetermined time duration in accordance with a pulse evaluation process;
measuring at least one measurement voltage within a voltage response after providing the excitation pulse;
providing an indication of a presence or absence of an object to be detected in a detection area of the sensor coil;
   wherein the state of adjacent proximity sensors is received which indicates if or when a pulse evaluation process is active there, and that the pulse evaluation process is started only when no pulse evaluation process is active in an adjacent proximity sensor.

### BRIEF DESCRIPTION OF THE DRAWINGS

Embodiments are explained in more detail below with reference to the accompanying drawings, wherein:

FIG. 1 shows a schematic representation of an inductive proximity sensor including a synchronization unit;

FIG. 2 shows signal timing diagrams of the pulse control voltage, the switching signal, the coil current, the coil voltage and the voltage at the analog-to-digital converter;

FIG. 3 shows a flowchart for illustrating a process as performed in a control unit of a proximity sensor; and

FIG. 4 shows signal timing diagrams of the synchronization line potential, the coil currents of two proximity sensors and the two analog-to-digital converter voltages of the proximity sensors; and

FIG. 5 shows a schematic representation of an inductive proximity sensor including a synchronization unit in which a measurement of the second measurement voltage is suppressed.

### DESCRIPTION OF EMBODIMENTS

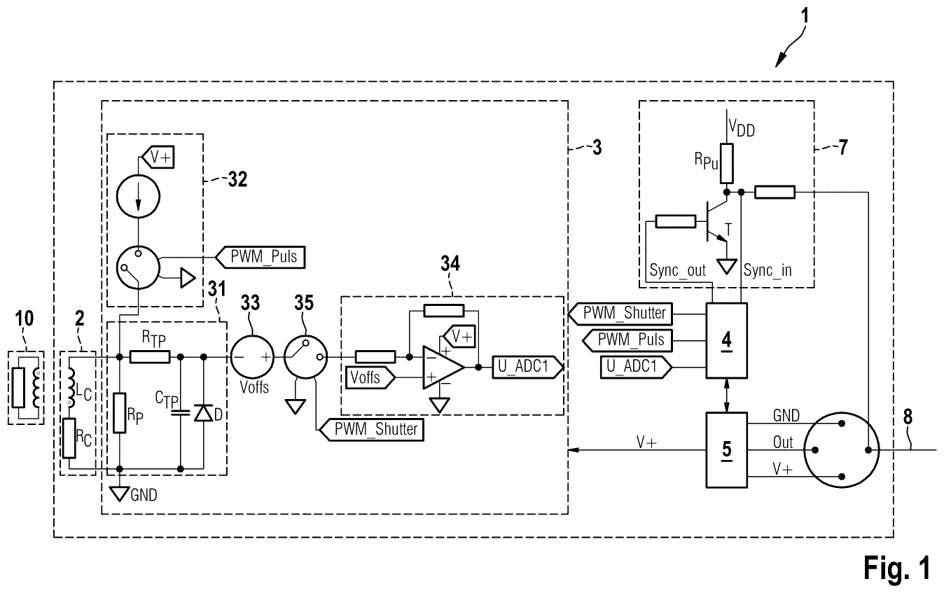

FIG. 1 is a schematic representation of an inductive proximity sensor 1 according to an embodiment of the invention.

The proximity sensor 1 comprises a sensor coil 2 including an inductance L_{C} and a parasitic resistance R_{C}, which is electrically connected to a pulse evaluation circuit 3. The pulse evaluation circuit 3 has a passive network 31 that is connected in parallel to the sensor coil 2.

The sensor coil 2 is serially connected to a switchable current source 32 in order to cyclically apply a current pulse to the sensor coil 2 under the control of a pulse control signal PWM_Puls from a control unit 4.

The passive network 31 comprises a discharge resistor Rp, an RC low-pass resistor R_{TP}, C_{TP} and a diode D. Shortly after the current source 32 is switched off, the voltage response is initially dominated by the self-induction pulse of the coil. The passive network 31 serves to limit the self-induction pulse with respect to its level for protecting the subsequent circuit components.

The sensor coil 2 serves as a probe for the proximity sensor 1 and generates a magnetic field. According to a pulse evaluation process, current pulses are impressed into the sensor coil 2 such that the voltage response of the induced voltage, which is determined by the self-induction and the conductivity and permeability of the object 10 to be detected, depends on the presence or absence of the object 10 to be detected in the detection area.

Furthermore, an offset voltage-source 33 of the pulse evaluation circuit 3 may be connected to the sensor coil 2 in order to apply a voltage offset V_{offs} to the resulting voltage response in order to put the voltage response into a suitable voltage measurement range.

By means of an amplifier circuit 34, which may include an operational amplifier 341, measurement voltages U_ADC1 of the voltage response may be amplified at certain points in time, and may be measured by means of an analog-to-digital converter in the control unit 4. For this purpose, the control unit 4 may include a microcontroller into which an AD converter is integrated in order to provide the measurement voltage in digitized form.

In order to avoid a saturation of the operational amplifier of the amplifier circuit 34 and an indefinitely long recovery time associated therewith, the voltage response of the sensor coil 2 may be temporarily disconnected from the amplifier input by means of an analog switch 35. If the analog switch 35 is opened at the beginning of the current pulse, and is closed again only some time, e.g. between 10 and 50 μs, after the coil current is switched off, the self-induction pulse, i.e. the voltage level of the voltage response, has decayed to such an extent that an amplifier saturation is excluded. The analog switch 35 is also controlled by the control unit 4 by means of a corresponding switching signal PWM_Shutter.

The evaluation of the voltage response is also controlled by the control unit 4 by measuring two measurement voltages with a predetermined time interval.

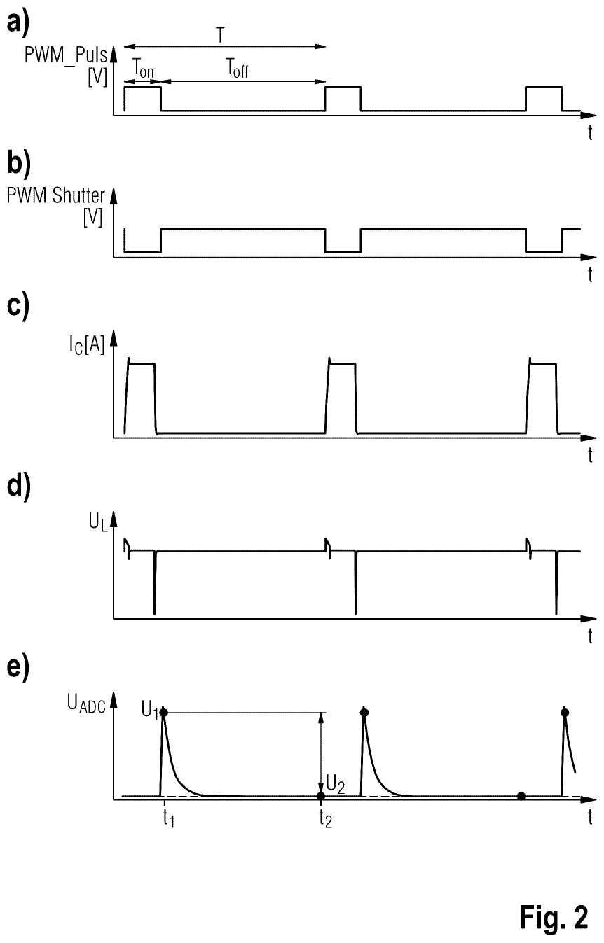

FIG. 2 schematically shows signal timing diagrams to illustrate the performing of the pulse evaluation process. It can be seen that the current pulse signal of the coil current I_{C}, which is provided by the control unit 4 using the current pulse signal PWM_Puls, causes a current pulse to be applied to the sensor coil 2. The current pulse is shown in FIG. 2c. Due to the falling edge of the current pulse I_{C}, i.e. the current drops to 0 Ampere, an induction of a voltage takes place in the sensor coil, which slowly dissipates via the passive network 31.

In order to avoid an overvoltage for subsequent circuit parts, the analog switch is controlled using the switching signal PWM_Shutter (FIG. 2b) in such a way that it switches on the analog switch 35 only after a short period of time after reaching 0 A or after the falling edge of the current pulse, thereby applying die voltage response of the sensor coil 2 to the amplifier circuit 34 only when it has already decayed to some extent. The voltage response is illustrated in the course of FIG. 2e.

The voltage measurements of the measurement voltages are carried out at predetermined points in time t1 and t2 which may be defined based on the time of the falling edge of the current pulse signal PWM_Puls. The voltage difference between the measurement voltages therefore allows a measurement of an indication regarding the mutual inductance of the object to be detected which acts on the sensor coil 2, and which depends on the presence or absence of the object 10 to be detected.

The first measurement voltage U1 at the point in time t1 corresponds approximately to the level of the voltage response, and the second measurement voltage U2 at the point in time t2 corresponds to a reference voltage which serves as a reference or reference voltage for the first measurement voltage which has been measured first.

The voltage difference may be provided as an output signal via a suitable interface 6. Alternatively, the result of a threshold value comparison of this voltage difference may be performed using a predetermined threshold value of this voltage difference, and the result of the threshold value comparison may be provided via the interface 5. The result of the threshold value comparison then corresponds to an indication of the presence or absence of an object 10 to be detected.

A synchronization unit 7 is provided to synchronize the operation of the proximity sensor 1 with the operation of an adjacently arranged proximity sensor 1, in particular to eliminate disturbing influences during measurement using the pulse evaluation process. The synchronization unit 7 is connected to one or more proximity sensors 1 via a synchronization line 8. The synchronization line 8 thus connects several proximity sensors 1 to each other which are each provided with a synchronization unit.

The synchronization unit 7 comprises a pull-up-resistor R_{PU} in order to impress a first voltage potential VDD on the synchronization line 8. The synchronization line 8 is, where applicable, connected to the control unit 4 via a protection resistor with a synchronization input Sync_In.

The synchronization unit 7 of the respective proximity sensor 1 is connected to the control unit 4, and may impress, under the control of a synchronization output Sync_Out by means of a transistor T, through which the synchronization line 8 is connected to a second lower voltage potential GND, a second voltage potential on the synchronization line 8. Thus, the synchronization unit 7 comprises a driver for applying to apply, under the control of a synchronization signal at the synchronization output Sync_Out, a second voltage level to the synchronization line 8. If the transistor T is closed, the second voltage potential is applied to the synchronization line. If it is opened, the pull-up-resistor R_{PU} pulls the voltage level of the synchronization line 8 to the first voltage potential.

The voltage level on the synchronization line 8 may be detected by the control unit 4 via the synchronization input Sync_In in order to control the performing of the pulse evaluation process accordingly.

The synchronization line 8 of the proximity sensors may also be respectively connected to a higher-level controller. In this case, the controller may selectively start and stop the pulse evaluation processes of the proximity sensors by specifically selecting suitable voltage levels of the synchronization line 8, and may thus allow an undisturbed operation of adjacent proximity sensors. For this purpose, the controller may evaluate on the one hand the synchronization signal in order to determine which of the proximity sensors actively performs a pulse evaluation process at present. This may be carried out for example by coding via the magnitude of the second voltage level. On the other hand, the controller may actively block the start of a pulse evaluation process in that the control causes a second voltage level on the synchronization line 8.

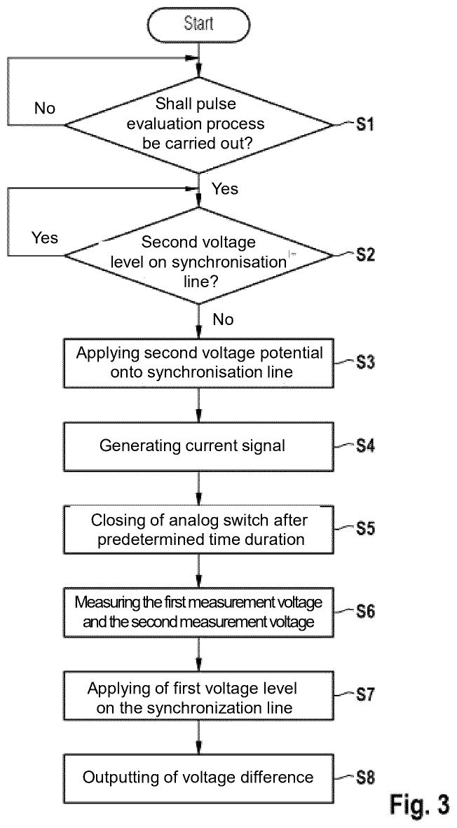

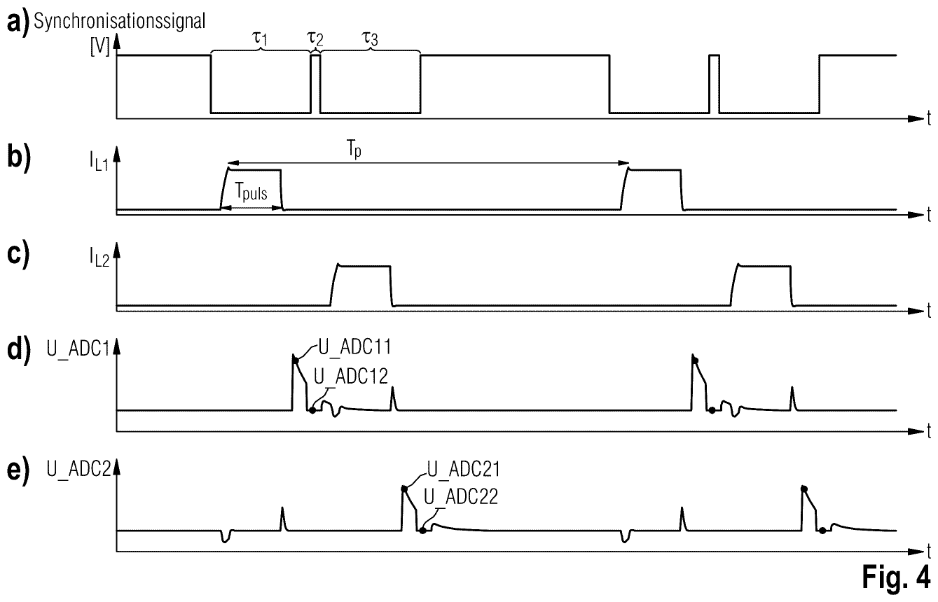

FIG. 3 shows a flowchart illustrating a method for operating a sensor system including several inductive proximity sensors 1. The process is further explained in the signal-to-time-diagrams of FIG. 4. The course of the process is controlled by the control units 4 of the proximity sensors 1 and generally takes place periodically according to a predetermined cycle frequency of the operation of the pulse evaluation process in each of the control units 4. Here, the pulse evaluation processes are performed with a time delay without overlapping. The process starts with an open analog switch 35.

In step 1, it is checked by the control of an internal clock, whether a pulse evaluation process is to be performed actively. If this is the case (alternatively: Yes), the process is continued at step S2. Otherwise (alternatively: No), the process returns to step S1.

In step S2, the voltage level of the voltage on the synchronization line 8 is first queried, and the applied voltage level is checked. If it is determined in step S2 that the second voltage level is applied which indicates that a pulse evaluation process is still active for another of the proximity sensors 1 (alternative: Yes), the process returns to step S2 and waits until the voltage level on the synchronization line 8 rises again to the first voltage level. If it is determined that the first voltage level is reached, and that therefore no other pulse evaluation process is active (alternative: No), then the process is continued with step S3.

In step S3, the synchronization output Sync_Out of the control unit 4 is activated, thereby closing the transistor T, and thus lowering the voltage potential on the synchronization line 8 to the second voltage level. This signals to the other proximity sensors 1 on the synchronization line 8 that no measurements may take place using the pulse evaluation process.

At the same time or shortly after (e.g. between 1 to 100 μs), the pulse evaluation process is started in step S4 by applying the current pulse signal PWM_Puls for applying the current pulse, and the current pulse signal PWM_Puls is generated for a predetermined period of time which applies a current pulse to the sensor coil 2 via the switched current source 32. This is shown for the proximity sensors 1 in the diagrams of FIGS. 4b and 4c. The current pulse has a predetermined duration T_{Puls} which may be significantly lower, i.e. less than 20% or less than 10% of the period duration Tp of the cyclic pulse evaluation process.

If the duration of the current pulse is elapsed, i.e. there is, for example, a falling slope of the coil current, or the coil current has reached 0 A, the analog switch 35 which has been opened before is closed in step S5 after a short first period of time of, for example, between 10 and 50 μs by means of the switching signal PWM_Shutter, in order to apply a voltage of the voltage response, which has already been decayed to some extent, to the amplifier circuit 34.

After a predetermined second duration of time at the point in time t1 after reaching 0 amperes after the current pulse has been applied, a first measurement voltage U_ADC11 is measured in step S6, and a second measurement voltage U_ADC12 is measured at a later point in time t2 which is defined by a predetermined third time period after reaching 0 amperes after the current pulse. The measurement is performed with the analog-digital converter of the control unit 4. In an analog manner, a first and a second measurement voltage U_ADC21, U_ADC22 are obtained for the other proximity sensor.

In step S7, immediately after the measurement of the second measurement voltage 8, the synchronization line 8 is released again and the synchronization output Sync_Out of the control unit 4 is deactivated. This opens the transistor T, and thus raises the voltage potential on the synchronization line 8 to the first voltage level. The pulse evaluation process is then completed, and a pulse evaluation process may be performed by the other proximity sensor on the synchronization line 8.

In step S8, the voltage difference between the first and the second measurement voltage can serve as an output signal, or may be used for generating the output signal as described above. In particular, this (threshold value comparison based on differential voltage) can provide an indication regarding the presence or absence of an object 10 to be detected in a detection area of the sensor coil 2.

The number of proximity sensors in the sensor system may also be more than two, wherein, however, the sum of the durations of the pulse evaluation processes of all proximity sensors must be smaller than the total period duration T_{P} of the individual proximity sensors.

If it is determined in step S2 that the second voltage level is present on the synchronization line 8 for more than a predetermined time period, such as two period durations T_{P}, the measurement may be started regardless of the voltage level on the synchronization line 8. This excludes the case that the voltage level of the synchronization line 8 remains at the second voltage level due to an error.

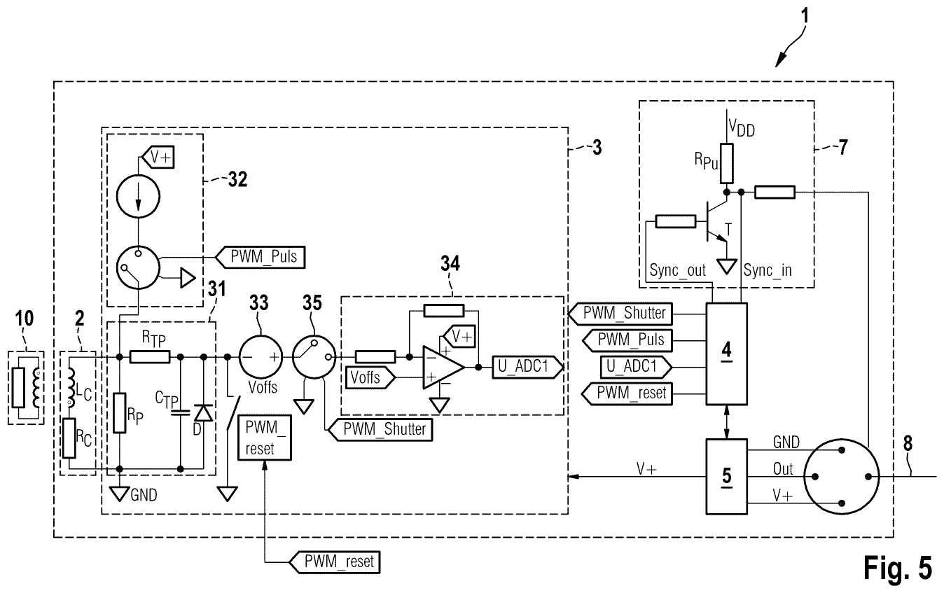

FIG. 5 shows a schematic representation of an inductive proximity sensor with a synchronization unit 7, in which a measurement of the second measurement voltage is suppressed. A short-circuit switch 36 is provided for this purpose, which is arranged in parallel to the passive network 31 and short-circuits the voltage drop across the network 31 under the control of a reset signal PWM_reset of the control unit 4. Since the resistance R_{P} is generally selected to be significantly lower than R_{TP}, the closing of the short-circuit switch 36 has no influence on the energy of the sensor coil 2. The short-circuiting of the network 31 serves to suppress the signal of the sensor coil 2 in order to be able to measure the offset voltage of the offset voltage source 33 and any additional offset voltage of the amplifier circuit without being influenced by the voltage of the sensor coil. Thus, the second measurement voltage, which should correspond to the voltage of the offset voltage source 33 plus any offset voltage of the subsequent circuit parts 34 and 35 may be measured at any time without being influenced by any coupled interference (e.g. by the interfering field of an adjacent sensor).

The determination of the voltage difference may therefore only be falsified at one point in time, namely the first point in time t₁. This effectively halves the probability of interference and also allows significantly more flexible and shorter pulse evaluation processes, as it is not absolutely necessary to wait for the end of the voltage response to determine the pulse offset using the second measurement voltage. The voltage level on the synchronization line 8 may therefore also be set to the first voltage level immediately after the measurement of the first measurement voltage, so that other proximity sensors of the sensor system may start the pulse evaluation process.

The purpose of the synchronization signal is to signal in a simple way when a pulse evaluation process is active in one of the proximity sensors connected to the synchronization line. In addition to voltage levels, signaling may also take place by applying or transmitting PWM signals, oscillation signals or digital signals that contain information about the time of the start of the pulse evaluation process, the duration of the pulse evaluation process and/or an identification of the proximity sensor in which the pulse evaluation process is currently active. This allows predefined measurement sequences to be implemented, for example, especially if more than two sensors are connected to the synchronization line, which is advantageous for the precise evaluation of object speeds, for example.

A measurement with different measuring rates in the plurality of proximity sensors may also be implemented in order to meet different requirements with respect to the measurement application.

Furthermore, the synchronization signal could also have more than two voltage levels in order to be able to distinguish between different phases of the pulse evaluation process, e.g. the phase in which the coil current increases, the phase in which the coil current is constant (not equal to zero), the phase in which the coil current decreases and the phase in which measurement values are recorded. This enables, for example, the synchronization with a phase position in which a first proximity sensor detects measurement values while the coil current of the second adjacent proximity sensor is constant but not equal to zero, and therefore no interference voltage is induced in the sensor coil of the first proximity sensor. As a result, the maximum number of proximity sensors that may be synchronized via the synchronization line for a given pulse period may be increased.

1. An inductive proximity sensor, comprising:
a sensor coil;
a pulse evaluation circuit which is configured to provide an excitation pulse for the sensor coil and to obtain a resulting voltage response;
a control unit which is configured
to control the pulse evaluation circuit according to a pulse evaluation process such that the sensor coil is excited by an excitation pulse of a predetermined duration of time;
to detect at least a first measurement voltage at a specific first point in time after providing the excitation pulse, and
to provide an indication regarding the presence or absence of an object to be detected in a detection area around the sensor coil in dependence on the first measurement voltage,
characterized in that
a synchronization unit is provided in order to receive a synchronization signal which indicates if or when a pulse evaluation process is active in an adjacent proximity sensor, and in that the control unit is configured to start the pulse evaluation process in dependence on the synchronization signal.

2. The inductive proximity sensor according to claim 1, wherein the control unit is configured to start the pulse evaluation process only if no pulse evaluation process is active in an adjacent proximity sensor.

3. The inductive proximity sensor according to claim 1, wherein the synchronization unit is configured to signal the time and the duration of the active pulse evaluation process under the control of the control unit.

4. The inductive proximity sensor according to claim 1, wherein the control unit is configured to, when it is detected that the pulse evaluation process is active in an adjacent proximity sensor, start the pulse evaluation process when the pulse evaluation process in the adjacent proximity sensor has ended.

5. The inductive proximity sensor according to claim 1, wherein an electric synchronization line (8) is provided to transmit the synchronization signal.

6. The inductive proximity sensor according to claim 1, wherein the synchronization signal indicates by a first voltage level that no pulse evaluation process is active, and indicates by a second voltage level that a pulse evaluation process is active.

7. The inductive proximity sensor according to claim 6, wherein the control unit is configured to apply the voltage level of the synchronization signal to the second voltage level when or before the stimulating pulse is being provided and/or to apply the voltage level of the synchronization signal to the first voltage level after at least the first measurement voltage has been detected.

8. The inductive proximity sensor according to claim 1, wherein the control unit is configured to start the pulse evaluation process if the synchronization signal indicates for more than a predetermined time period that a pulse evaluation process is active in an adjacent proximity sensor.

9. The inductive proximity sensor according to claim 1, wherein the control unit is configured to determine a voltage difference between the first measurement voltage and a second measurement voltage, and to provide it as an indication of the presence or absence of an object to be detected in a detection area of the sensor coil, wherein the control unit is configured to detect the second measurement voltage at a particular second point in time after providing the stimulating pulse after the first point in time.

10. The inductive proximity sensor according to claim 9, wherein a short-circuit switch is provided in order to specify the second measurement voltage as a reference voltage at the time of its measurement.

11. A sensor system comprising a plurality of proximity sensors according to claim 1, wherein the proximity sensors are connected to each other via a synchronization line.

12. A method for operating an inductive proximity sensor including a sensor coil; including the following steps:
providing an excitation pulse to apply on the sensor coil for a predetermined time period according a pulse evaluation process;
measuring of at least one measurement voltage within a voltage response after providing the excitation pulse;
providing an indication of a presence or absence of an object to be detected in a detection area of the sensor coil in dependence on the at least one measurement voltage;
characterized in that
the state of adjacent proximity sensors is received which indicates if or when a pulse evaluation process is active there, and that the pulse evaluation process is only started if no pulse evaluation process is active in an adjacent proximity sensor.
